(19) United States
(12) Patent Application Publication
(10) Pub. No.: US 2014/0318843 A1
(43) Pub. Date: Oct. 30, 2014

(54) MULTILAYER CERAMIC ELECTRONIC COMPONENT AND MOUNTING BOARD THEREFOR

(71) Applicant: SAMSUNG ELECTRO-MECHANICS CO., LTD., Suwon (KR)

(72) Inventors: Byung Woo HAN, Suwon (KR); Dae Bok OH, Suwon (KR); Jae Yeol CHOI, Suwon (KR); Sang Huk KIM, Suwon (KR)

(73) Assignee: SAMSUNG ELECTRO-MECHANICS CO., LTD., Suwon (KR)

(21) Appl. No.: 13/952,577

(22) Filed: Jul. 26, 2013

(30) Foreign Application Priority Data
Apr. 30, 2013 (KR) 10-2013-0048126

(51) Int. Cl. H01G 4/30; H05K 1/18

(52) U.S. Cl. CPC H01G 4/30; H05K 1/181
USPC 174/260; 361/301.4

(57) ABSTRACT

There is provided a multilayer ceramic electronic component including a ceramic body satisfying T/W>1.0 when a width and a thickness thereof are defined as W and T, respectively, a plurality of first and second internal electrodes having the respective dielectric layers interposed therebetween, and alternately exposed through both end surfaces of the ceramic body, and first and second external electrodes formed to be extended from the both end surfaces to both upper and lower main surfaces of the ceramic body, wherein, the ceramic body is formed such that a cross-section thereof in a width-thickness direction has a trapezoidal shape in which two sides among four sides are inclined in one direction, and when an angle formed by a bottom side and a side connected thereto is defined as θ, 86°≦θ<90° is satisfied.

### CROSS-REFERENCE TO RELATED APPLICATIONS

This application claims the priority of Korean Patent Application No. 10-2013-0048126 filed on Apr. 30, 2013, in the Korean Intellectual Property Office, the disclosure of which is incorporated herein by reference.

### BACKGROUND OF THE INVENTION

1. Field of the Invention

The present invention relates to a multilayer ceramic electronic component and a mounting board therefor.

2. Description of the Related Art

In accordance with the recent trend for miniaturization of electronic products, demands have been made for a multilayer ceramic electronic component used in the electronic products to have a smaller size and higher capacitance.

Therefore, dielectric layers and internal electrodes have been thinned and stacked in increasing amounts through various methods. Recently, as a thickness of individual dielectric layers has been reduced, multilayer ceramic electronic components having increased amounts of stacked layers included therein have been manufactured.

Therefore, multilayer ceramic electronic components may be miniaturized, and the dielectric layers and internal electrodes may be thinned, such that the dielectric layers and internal electrodes have been stacked in increasing amounts in order to implement a high degree of capacitance.

However, in a case in which dielectric layers and internal electrodes are thinned and stacked in an increased amount, although a high capacitance multilayer ceramic electronic component may be realized, but the multilayer ceramic electronic component may have a thickness thereof larger than a width thereof, due to the increase in stacked layers.

As described above, when a multilayer ceramic electronic component has a thickness larger than a width, external electrodes provided on both end surfaces of the multilayer ceramic electronic component may generally have circumferential surfaces having round shapes.

Therefore, when the multilayer ceramic electronic component is mounted on a printed circuit board, the multilayer ceramic electronic component may not be maintained in a state thereof in which it is initially mounted on the board, and may frequently topple over. Hence, a mounting failure rate of the multilayer ceramic electronic component is increased.

Patent Document 1 discloses a multilayer ceramic capacitor having a smaller size and higher capacitance. However, Patent Document 1 does not disclose an element or a method for solving a defect in which the multilayer ceramic capacitor topples over when being mounted on a printed circuit board.

### RELATED ART DOCUMENT

(Patent Document 1) Japanese Patent Laid-open Publication No. 2005-129802

### SUMMARY OF THE INVENTION

An aspect of the present invention provides a multilayer ceramic electronic component, capable of decreasing amounting failure and the occurrence of a short-circuit by solving a defect in which the multilayer ceramic electronic component topples over when being mounted on a printed circuit board or the like, while having high capacitance due to a thickness thereof being larger than a width thereof in accordance with an increase in the number of stacked layers included therein.

According to an aspect of the present invention, there is provided a multilayer ceramic electronic component including a ceramic body including a plurality of dielectric layers stacked in a thickness direction and satisfying T/W>1.0 when a width and a thickness thereof are defined as W and T, respectively, a plurality of first and second internal electrodes disposed in the ceramic body to face each other, having the respective dielectric layers interposed therebetween, and alternately exposed through both end surfaces of the ceramic body, and first and second external electrodes formed to be extended from the both end surfaces to both upper and lower main surfaces of the ceramic body, and electrically connected to the first and second internal electrodes, respectively, wherein the ceramic body is formed such that a cross-section thereof in a width-thickness direction has a trapezoidal shape in which two sides among four sides are inclined in one direction, and when an angle formed by a bottom side and a side connected thereto is defined as θ, 86°≦θ<90° is satisfied.

According to another aspect of the present invention, there is provided a multilayer ceramic electronic component including a ceramic body including a plurality of dielectric layers stacked in a width direction and satisfying T/W>1.0 when a width and a thickness thereof are defined as W and T, respectively, a plurality of first and second internal electrodes disposed in the ceramic body to face each other, having the respective dielectric layers interposed therebetween, and alternately exposed through both end surfaces of the ceramic body, and first and second external electrodes formed to be extended from the both end surfaces to both upper and lower main surfaces of the ceramic body, and electrically connected to the first and second internal electrodes, respectively, wherein, the ceramic body is formed such that a cross-section thereof in a width-thickness direction has a trapezoidal shape in which two sides among four sides are inclined in one direction, and when an angle formed by a bottom side and a side connected thereto is defined as θ, 86°≦θ<90° is satisfied.

The plurality of first and second internal electrodes may be disposed to be offset from each other in a width direction in accordance with a cross-sectional shape of the ceramic body in the width-thickness direction, in which the two sides thereof are inclined.

The plurality of first and second internal electrodes may be inclined in accordance with a cross-sectional shape of the ceramic body in the width-thickness direction, in which the two sides thereof are inclined.

When an average thickness of the respective dielectric layers is defined as td, 0.1 μm≦td≦0.6 μm may be satisfied.

The first and second internal electrodes may respectively have a thickness of 0.6 μm or less.

When an average thickness of the respective dielectric layers is defined as td and a thickness of the respective first and second internal electrodes is defined as te, te/td≦0.833 may be satisfied.

The dielectric layers may be stacked in an amount of 500 layers or more.

According to another aspect of the present invention, there is provided a mounting board for a multilayer ceramic electronic component, the mounting board including: a printed circuit board having first and second electrode pads provided thereon; and the above multilayer ceramic electronic component disposed on the first and second electrode pads.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a partially cut-away perspective view of a multilayer ceramic capacitor according to an embodiment of the present invention;

FIG. 2 is a cross-sectional view taken along line A-A′ of FIG. 1;

FIG. 3 is a cross-sectional view showing another example of first and second internal electrodes of the multilayer ceramic capacitor according to an embodiment of the present invention;

FIG. 4 is a partially cut-away perspective view of a multilayer ceramic capacitor according to another embodiment of the present invention;

FIG. 5 is a cross-sectional view taken along line B-B′ of FIG. 4;

FIG. 6 is a cross-sectional view showing another example of first and second internal electrodes of the multilayer ceramic capacitor according to another embodiment of the present invention; and

FIG. 7 is a partially cut-away perspective view of the multilayer ceramic capacitor according to an embodiment of the present invention according to an embodiment of the present invention, mounted on a printed circuit board.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein.

Rather, these embodiments are provided so that this disclosure will be thorough and complete, and will fully convey the scope of the invention to those skilled in the art.

In the drawings, the shapes and dimensions of elements may be exaggerated for clarity.

In addition, the same reference numerals will be used throughout to designate the same or like elements.

Hereinafter, the multilayer ceramic electronic component according to an embodiment of the present invention will be described. Particularly, a multilayer ceramic capacitor will be described by way of example. However, the present invention is not limited thereto.

### Multilayer Ceramic Capacitor

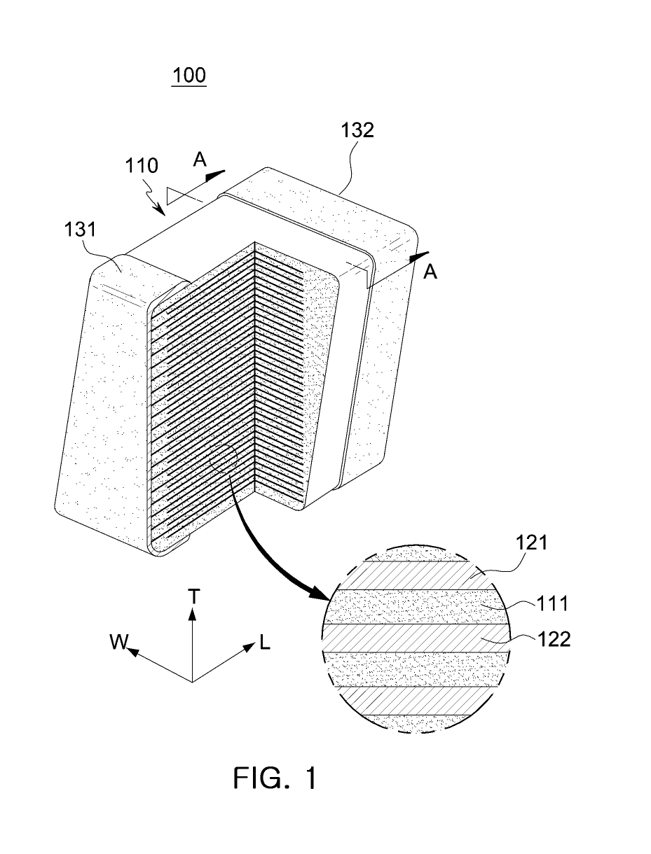

FIG. 1 is a partially cut-away perspective view of a multilayer ceramic capacitor according to an embodiment of the present invention.

Referring to FIG. 1, a multilayer ceramic capacitor 100 according to an embodiment of the present invention may include a ceramic body 110, a plurality of first and second internal electrodes 121 and 122, and first and second external electrodes 131 and 132.

The ceramic body 110 may be formed by stacking a plurality of dielectric layers 111 in a thickness direction and performing sintering, and the plurality of dielectric layers 11 may be integrated so as not to confirm boundaries between the adjacent dielectric layers without a scanning electron microscope (SEM).

The ceramic body 110 is not particularly limited in terms of the shape thereof and, for example, may have a hexahedral shape.

When defining directions of a hexahedron of the ceramic body 110 in order to clearly explain the embodiment of the present invention, L, W and T shown in the drawings refer to a length direction, a width direction and a thickness direction, respectively.

Furthermore, in the present embodiment, for the convenience of explanation, surfaces of the ceramic body 110 facing each other in a thickness direction are defined as first and second main surfaces, surfaces of the ceramic body 110 connecting the first and second main surfaces to each other and facing each other in a length direction are defined as first and second end surfaces, and surfaces of the ceramic body 110 facing each other in a width direction are defined as first and second side surfaces.

The ceramic body 110 may be formed by increasing the number of the dielectric layers 111 stacked therein in order to implement high capacitance, and when a width and a thickness of the ceramic body 110 are defined as W and T, respectively, T/W>1.0 is satisfied, such that the ceramic body 110 may have the thickness thereof lager than the width thereof.

The number of the stacked dielectric layers 111 is not particularly limited, but for example, 500 or more dielectric layers 111 may be stacked in order to realize high capacitance while securing a sufficient space therefor when being mounted on a board.

The dielectric layers 111 may include a ceramic material having a high dielectric constant, for example, a barium titanate (BaTiO₃) based ceramic powder. However, a material for the dielectric layers according to the embodiment of the present invention is not limited thereto, as long as a sufficient capacitance may be obtained thereby.

Furthermore, the dielectric layers 111 may include a ceramic powder and further include various types of ceramic additives such as a transition metal oxide or transition metal carbide, rare earth elements, and magnesium (Mg) or aluminum (Al), an organic solvent, a plasticizer, a binder and a dispersant, along with the ceramic powders.

In this case, when an average thickness of the dielectric layers 111 is defined as td, 0.1 μm≦td≦0.6 μm may be satisfied in order to manufacture a multilayer ceramic capacitor having a subminiature size and ultra-high capacitance, but the present invention is not limited thereto.

The average thickness td of the dielectric layers 111 may be measured from an image obtained by scanning a cross-section of the ceramic body 110 in the width direction using a scanning electron microscope (SEM).

For example, the average thickness may be calculated by measuring respective thicknesses of a dielectric layer at thirty points thereof having equal intervals therebetween in a width direction, the dielectric layer being extracted from the image obtained by scanning the cross-section of the ceramic body 110 in a width-thickness (W-T) direction cut in a central portion of the ceramic body 110 in the length (L) direction, using the scanning electron microscope (SEM).

The thirty points having equal intervals therebetween may be measured in a region in which the first and second internal electrodes 121 and 122 overlap each other to form capacitance.

Furthermore, when such a measurement of the average thickness is performed on 10 or more dielectric layers, the average thickness of the dielectric layers may be more generalized.

The first and second internal electrodes 121 and 122 are electrodes having different polarities and disposed to face each other, having a ceramic sheet forming each dielectric layer 111 interposed therebetween. The first and second internal electrodes 121 and 122 may be formed in the ceramic body 110 to be exposed through the first and second end surfaces of the ceramic body 110.

Then, the first and second internal electrodes 121 and 122 may be electrically insulated from each other by the respective dielectric layers 111 disposed therebetween.

Further, the first and second internal electrodes 121 and 122 are formed of a conductive metal, for example, one of silver (Ag), palladium (Pd), platinum (Pt), nickel (Ni), and copper (Cu) or an alloy thereof, however, the invention is not limited thereto.

Furthermore, the average thickness of the first and second internal electrodes 121 and 122 is not specifically limited, as long as capacitance may be formed thereby. For example, the average thickness may be 0.6 μm or less, however, the invention is not limited thereto.

When the average thickness of the respective first and second internal electrodes 121 and 122 is larger than 0.6 μm and is excessively increased, cracks may occur in the ceramic body 110.

The average thickness of the respective first and second internal electrodes 121 and 122 may be measured from an image obtained by scanning the cross-section of the ceramic body 110 in the width direction using the SEM.

For example, the average thickness may be calculated by measuring respective thicknesses of an internal electrode at thirty points thereof having equal intervals therebetween in the width direction, the internal electrode being extracted from the image obtained by scanning the cross-section of the ceramic body 110 in the width-thickness (W-T) direction cut in a central portion of the ceramic body 110 in the length direction L, using the scanning electron microscope (SEM).

The thirty points having equal intervals therebetween may be measured in the region in which the first and second internal electrodes 121 and 122 overlap each other to form capacitance.

Furthermore, when such a measurement of the average thickness is performed on 10 or more internal electrodes, the average thickness of the internal electrodes may be more generalized.

In addition, when the average thickness of the respective dielectric layers 111 is defined as td and the average thickness of the respective first and second internal electrodes 121 and 122 is defined as te, te/td≦0.833 may be satisfied. In this case, when a ratio te/td of the average thickness te of the respective first and second internal electrodes 121 and 122 to the average thickness td of the respective dielectric layers 111 is excessively large, an internal stress in the multilayer ceramic capacitor 100 may be increased due to a difference in sintering shrinkage between the dielectric layers 111 and the first and second internal electrodes 121 and 122. Therefore, the occurrence of cracks may be increased in the multilayer ceramic capacitor 100.

Therefore, te/td≦0.833 may be satisfied such that the occurrence of cracks in the multilayer ceramic capacitor 100 may be effectively prevented and connectivity of the first and second internal electrodes 121 and 122 may be improved so as to realize high capacitance.

The first and second external electrodes 131 and 132 are extended from the first and second end surfaces of the ceramic body 110 to the first and second main surfaces thereof, and are electrically connected to the plurality of the first and second internal electrodes 121 and 122 alternately exposed through the first and second end surfaces of the ceramic body 110. Then, the first and second external electrodes 131 and 132 may be extended from the first and second end surfaces of the ceramic body 110 to the first and second side surfaces thereof, in order to improve moisture-resistance properties.

Further, the first and second external electrodes 131 and 132 are formed of a conductive metal, for example, silver (Ag), nickel (Ni), copper (Cu) or the like. The first and second external electrodes 31 and 32 may be formed by applying a conductive paste prepared by adding a glass frit to a conductive metal powder to outer surfaces of the ceramic body 110 and performing a sintering process. The present invention is not limited thereto.

On the other hand, first and second plating layers (not shown) may be formed on the first and second external electrodes 131 and 132, if necessary.

When the multilayer ceramic capacitor 100 is mounted on a printed circuit board through solder, the first and second plating layers are provided to improve adhesion therebetween.

The first and second plating layers include, for example nickel (Ni) plating layers formed on the first and second external electrodes 131 and 132 and tin (Sn) plating layers formed on the nickel plating layers, but the invention is not limited thereto.

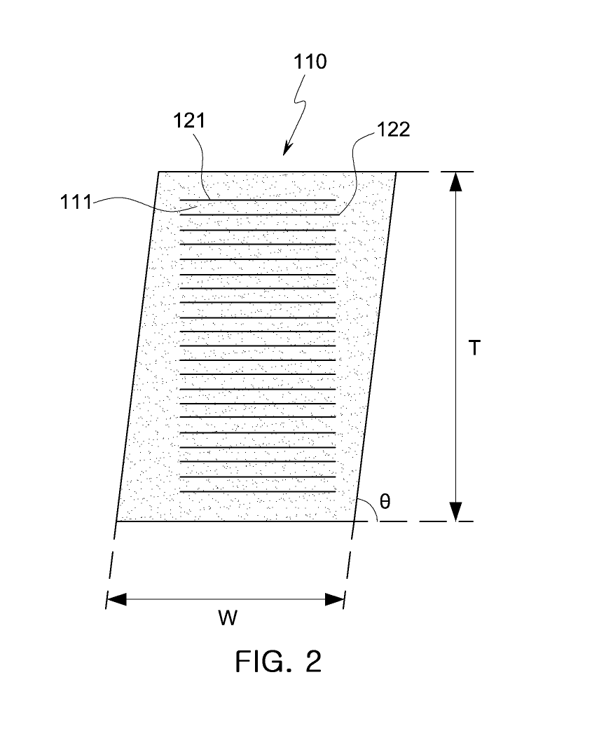

FIG. 2 is a cross-sectional view taken along line A-A′ of FIG. 1 and shows the cross-section of the ceramic body in the width-thickness direction according to an embodiment of the present invention.

Referring to FIG. 2, the ceramic body 110 may be formed such that the cross-section thereof in the width-thickness direction has a trapezoidal shape in which two sides among four sides are inclined in one direction. In this case, when an angle formed by a bottom side and a side connected thereto is defined as θ, 86°≦θ<90° may be satisfied.

The following Table 1 shows whether or not the multilayer ceramic capacitor 100 topples over when being mounted on a printed circuit board in accordance with the value of the angle θ, that is, an angle formed by a bottom side and a side connected thereto in the trapezoidal shaped cross-section of the ceramic body 110.

TABLE 1

Whether or not multilayer ceramic
capacitor topples over

| Samples | θ(°) | Frequency | Result |
|---|---|---|---|
| 1 | 84 | 2/50 | NG |
| 2 | 85 | 2/50 | NG |
| 3 | 86 | 0/50 | OK |
| 4 | 87 | 0/50 | OK |
| 5 | 88 | 0/50 | OK |
| 6 | 89 | 0/50 | OK |

Referring to Table 1, in the case of Samples 1 and 2, in which an angle θ formed by the mounting surface of the ceramic body, that is, a bottom side of the ceramic body and a side connected to the bottom side in the thickness direction is excessively small, such that the ceramic body is significantly inclined laterally, it may be confirmed that mounting failures in which a multilayer ceramic capacitor topples over twice when it is mounted on a printed circuit board fifty times were generated.

Further, Samples 4 to 6, in which the angle θ formed by the mounting surface of the ceramic body, that is, the bottom side of the ceramic body, and the side connected to the bottom side in the thickness direction is an appropriate angle, such that the ceramic body is appropriately inclined laterally, it may be confirmed that the multilayer ceramic capacitor 100 did not topple over when being mounted on the printed circuit board fifty times. Therefore, it could be confirmed that the value of θ value is in an appropriate range.

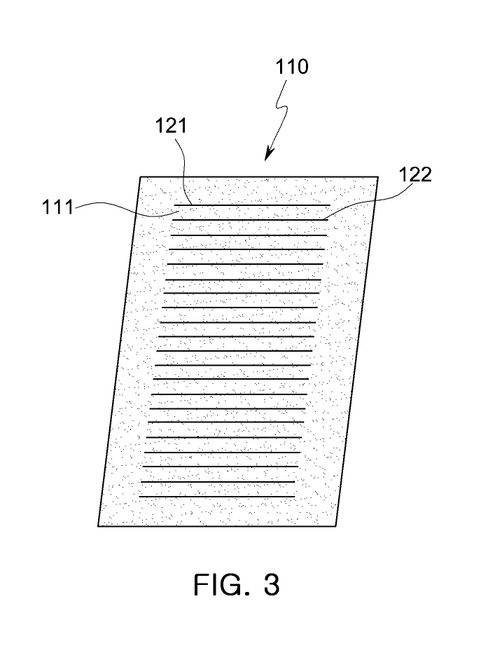

FIG. 3 is a cross-sectional view showing another example of first and second internal electrodes of the multilayer ceramic capacitor according to an embodiment of the present invention.

Referring to FIG. 3, the plurality of first and second internal electrodes 121 and 122 may be disposed to be offset from each other in the width direction in accordance with a cross-sectional shape of the ceramic body 110 in the width-thickness direction, in which the two sides thereof are inclined.

Here, a structure in which the ceramic body 110 and the first and second external electrodes 131 and 132 are formed is identical to that of the forgoing embodiment and hence, a description thereof is not repeatedly described.

### Modified Example

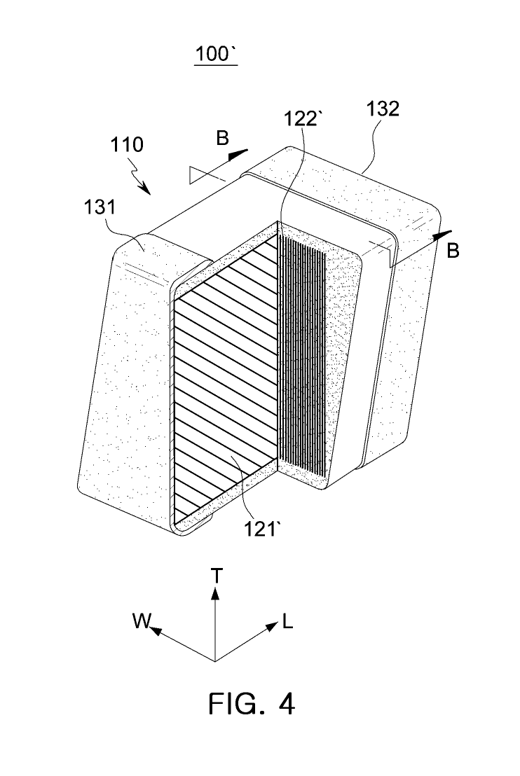

FIG. 4 is a partially cut-away perspective view of a multilayer ceramic capacitor according to another embodiment of the present invention.

A structure in which the first and second external electrodes 131 and 132 are formed is identical to that of the forgoing embodiment, and a description thereof is not repeatedly described. Thus, the first and second internal electrodes 121′ and 122′ having a different structure from that of the forgoing embodiment will be described in detail.

Referring to FIG. 4, a multilayer ceramic capacitor 100′ according to another embodiment of the present invention may include the ceramic body 110 including the plurality of the dielectric layers 111 stacked in the width direction.

Therefore, the first and second internal electrodes 121′ and 122′ are disposed to face each other in the width direction, having a ceramic sheet forming each dielectric layer 111 interposed therebetween. The first and second internal electrodes 122′ and 122′ may be formed in the ceramic body 110 to be exposed through the first and second end surfaces of the ceramic body 110. Then, the first and second internal electrodes 121′ and 122′ may be electrically insulated from each other by the dielectric layer 111 interposed therebetween.

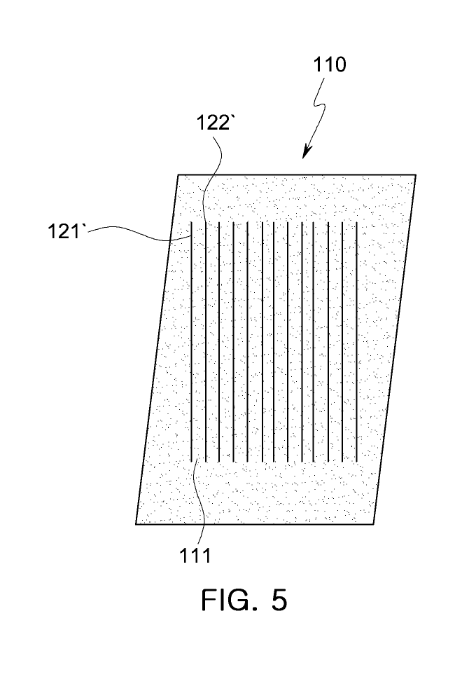

FIG. 5 is a cross-sectional view taken along line B-B′ of FIG. 4 and shows a cross-section of the ceramic body in the thickness-width direction according to another embodiment of the present invention.

Referring to FIG. 5, the ceramic body 110 may be formed such that the cross-section thereof in the width-thickness direction has a trapezoidal shape in which two sides among four sides are inclined in one direction. In this case, when an angle formed by a bottom side and a side connected thereto is defined as θ, 86°≦θ<90° may be satisfied.

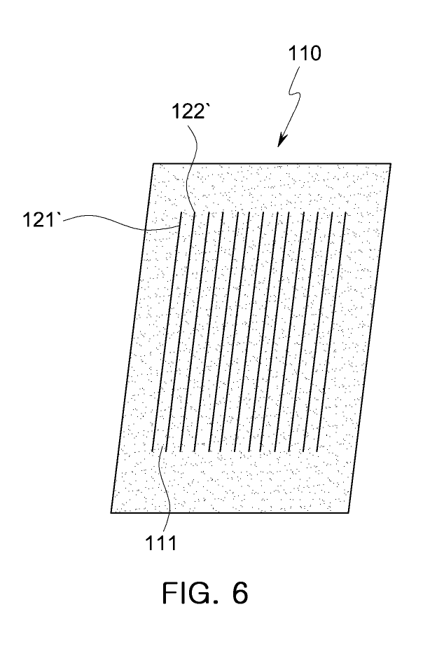

FIG. 6 is a cross-sectional view showing another example of first and second internal electrodes of the multilayer ceramic capacitor according to another embodiment of the present invention.

Referring to FIG. 6, the plurality of first and second internal electrode 121′ and 122′ may be inclined in accordance with a cross-sectional shape of the ceramic body 110 in the width-thickness direction, in which the two sides thereof are inclined.

Here, a structure in which the ceramic body 110 and the first and second external electrodes 131 and 132 are formed is identical to that of the foregoing embodiment, and hence a description thereof is not repeatedly described.

### Method of Manufacturing Multilayer Ceramic Capacitor

Hereinafter, a method of manufacturing a multilayer ceramic capacitor according to the embodiment of the present invention will be described.

First, a plurality of ceramic sheets are prepared. The ceramic sheets are provided to form the dielectric layers 111 of the ceramic body 110 and may be formed to have sheet shapes each having a thickness of several micrometers (μm) by mixing a ceramic powder, a polymer, a solvent, and the like to prepare a slurry, applying the slurry on carrier films using a doctor blade method or the like, and drying the slurry.

Next, a plurality of internal electrode patterns are formed while having predetermined intervals therebetween in a length direction by printing a conductive paste at a predetermined thickness on at least one surface of the ceramic sheet.

The conductive paste may be printed using a screen printing method, a gravure printing method, or the like, in order to form the internal electrode patterns. The present invention is not limited thereto.

Next, the plurality of ceramic sheets having the internal electrode patterns formed thereon are stacked in an amount of 500 layers or more such that the internal electrode patterns are alternately disposed from each other in the thickness direction, and are pressurized in the stacking direction thereof, such that a stacked body may be prepared.

Next, the stacked body is cut for each region corresponding to a single capacitor having a 0603 (length×width) standard in such as manner that a cross-section of the capacitor in a width-thickness direction has a trapezoidal shape in which two sides are inclined in one direction, such that chips each having a value of thickness/width lager than 1.0 are fabricated. The chips are fired at a high temperature of 1050 to 1200° C. and polished, to prepare the ceramic body 110 having the first and second internal electrodes 121 and 122.

Next, the first and second external electrodes 131 and 132 are formed on the first and second end surfaces of the ceramic body 110 such that exposed portion of the first and second internal electrodes 121 and 122 are electrically connected thereto, respectively.

In addition, if necessary, after the first and second external electrodes 131 and 132 are formed, the surfaces of the first and second external electrodes 131 and 132 may be subjected to a plating treatment using electric plating or the like to form first and second plating layers (not shown).

Then, when an angle formed by a bottom side and a side connected thereto in the trapezoidal cross-section of the ceramic body 110 is defined as θ, 86°≦θ<90° may be satisfied.

### Mounting Board for Multilayer Ceramic Capacitor

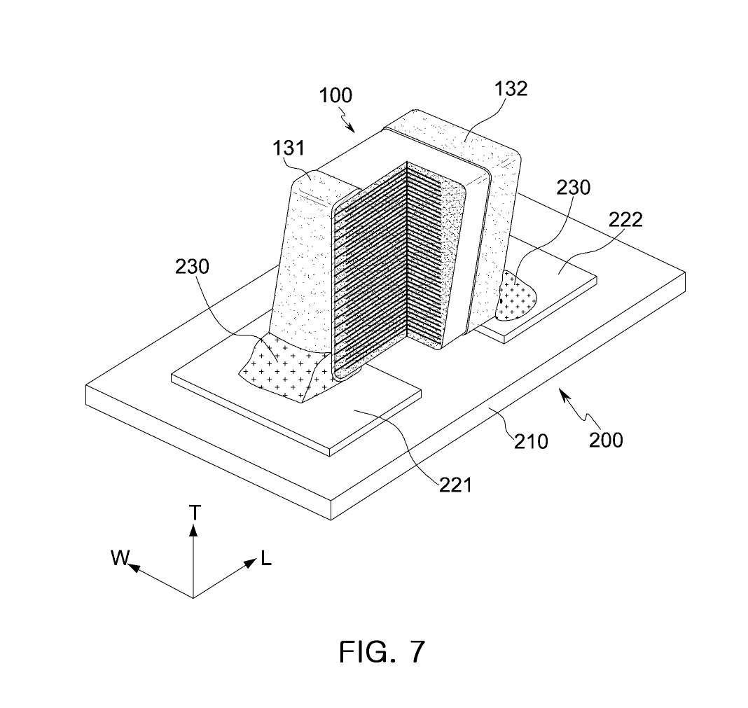

FIG. 7 is a partially cut-away perspective view of the multilayer ceramic capacitor according to an embodiment of the present invention according to an embodiment of the present invention, mounted on a printed circuit board.

Referring to FIG. 7, a mounting board 200 for the multilayer ceramic capacitor 100 according to an embodiment of the present invention may include a printed circuit board 210 having the multilayer ceramic capacitor 100 mounted thereon horizontally or vertically with respect to the printed circuit board 210; and first and second electrode pads 221 and 222 spaced apart from each other on an upper surface of the printed circuit board 210.

Here, the first and second external electrodes 131 and 132 of the multilayer ceramic capacitor 100 may be electrically connected to the printed circuit board 210 by a soldering part 230 while being positioned to contact the first and second electrode pads 221 and 222, respectively.

As set forth above, according to embodiments of the present invention, a multilayer ceramic capacitor may include a ceramic body formed in such a manner that a cross-section thereof in a width-thickness direction has a trapezoidal shape in which two sides are inclined in one direction and an angle formed by a bottom side and a side connected thereto in the cross-section thereof in the width-thickness direction is limited in a predetermined range, whereby a phenomenon in which circumferential surfaces of external electrodes are rounded can be significantly reduced to prevent the multilayer ceramic capacitor from toppling over when being mounted on a printed circuit board. Therefore, a multilayer ceramic electronic component in which mounting failures and short-circuits can be reduced while high capacitance is implemented in accordance with an increase in stacked layers can be provided.

While the present invention has been shown and described in connection with the embodiments, it will be apparent to those skilled in the art that modifications and variations can be made without departing from the spirit and scope of the invention as defined by the appended claims.

1. A multilayer ceramic electronic component, comprising:
a ceramic body including a plurality of dielectric layers stacked in a thickness direction and satisfying T/W>1.0 when a width and a thickness thereof are defined as W and T, respectively;
a plurality of first and second internal electrodes disposed in the ceramic body to face each other, having the respective dielectric layers interposed therebetween, and alternately exposed through both end surfaces of the ceramic body; and
first and second external electrodes formed to be extended from the both end surfaces to both upper and lower main surfaces of the ceramic body, and electrically connected to the first and second internal electrodes, respectively,
wherein, the ceramic body is formed such that a cross-section thereof in a width-thickness direction has a trapezoidal shape in which two sides among four sides are inclined in one direction, and when an angle formed by a bottom side and a side connected thereto is defined as θ, 86°≦θ<90° is satisfied.

2. The multilayer ceramic electronic component of claim 1, wherein the plurality of first and second internal electrodes are disposed to be offset from each other in a width direction in accordance with a cross-sectional shape of the ceramic body in the width-thickness direction, in which the two sides thereof are inclined.

3. The multilayer ceramic electronic component of claim 1, wherein when an average thickness of the respective dielectric layers is defined as td, 0.1 μm≦td≦0.6 μm is satisfied.

4. The multilayer ceramic electronic component of claim 1, wherein the first and second internal electrodes respectively have a thickness of 0.6 μm or less.

5. The multilayer ceramic electronic component of claim 1, wherein when an average thickness of the respective dielectric layers is defined as td and a thickness of the respective first and second internal electrodes is defined as te, te/td≦0.833 is satisfied.

6. The multilayer ceramic electronic component of claim 1, wherein the dielectric layers are stacked in an amount of 500 layers or more.

7. A multilayer ceramic electronic component, comprising:
a ceramic body including a plurality of dielectric layers stacked in a width direction and satisfying T/W>1.0 when a width and a thickness thereof are defined as W and T, respectively;
a plurality of first and second internal electrodes disposed in the ceramic body to face each other, having the respective dielectric layers interposed therebetween, and alternately exposed through both end surfaces of the ceramic body; and
first and second external electrodes formed to be extended from the both end surfaces to both upper and lower main surfaces of the ceramic body, and electrically connected to the first and second internal electrodes, respectively,
wherein, the ceramic body is formed such that a cross-section thereof in a width-thickness direction has a trapezoidal shape in which two sides among four sides are inclined in one direction, and when an angle formed by a bottom side and a side connected thereto is defined as θ, 86°≦θ<90° is satisfied.

8. The multilayer ceramic electronic component of claim 7, wherein the plurality of first and second internal electrodes are inclined in accordance with a cross-sectional shape of the ceramic body in the width-thickness direction, in which the two sides thereof are inclined.

9. The multilayer ceramic electronic component of claim 7, wherein when an average thickness of the respective dielectric layers is defined as td, 0.1 μm≦td≦0.6 μm is satisfied.

10. The multilayer ceramic electronic component of claim 7, wherein the first and second internal electrodes respectively have a thickness of 0.6 μm or less.

11. The multilayer ceramic electronic component of claim 7, wherein when an average thickness of the respective dielectric layers is defined as td and a thickness of the respective first and second internal electrodes is defined as te, te/td≦0.833 is satisfied.

12. The multilayer ceramic electronic component of claim 7, wherein the dielectric layers are stacked in an amount of 500 layers or more.

13. A mounting board for a multilayer ceramic electronic component, the mounting board comprising:
a printed circuit board having first and second electrode pads provided thereon; and
the multilayer ceramic electronic component of claim 1 disposed on the first and second electrode pads.
